(19) United States
(12) Patent Application Publication
(10) Pub. No.: US 2025/0038101 A1
(43) Pub. Date: Jan. 30, 2025

(54) Semiconductor Device and Method of Integrating eWLB with E-bar Structures and RF Antenna Interposer

(71) Applicant: STATS ChipPAC Pte. Ltd., Singapore (SG)

(72) Inventors: Ming-Che Hsieh, Hsinchu (TW); Linda Pei Ee Chua, Singapore (SG); Yaojian Lin, Jiangyin (CN)

(73) Assignee: STATS ChipPAC Pte. Ltd., Singapore (SG)

(21) Appl. No.: 18/357,361

(22) Filed: Jul. 24, 2023

(51) Int. Cl. H01L 23/50; H01L 21/48; H01L 21/56; H01L 23/00; H01Q 1/22

(52) U.S. Cl. CPC H01L 23/50; H01L 21/486; H01L 21/561; H01L 21/568; H01L 24/24; H01L 24/82; H01L 24/95; H01Q 1/2283; H01L 23/3128; H01L 2224/24155; H01L 2224/245; H01L 2224/821; H01L 2224/95; H01L 2924/01013; H01L 2924/01028; H01L 2924/01029; H01L 2924/01047; H01L 2924/0105; H01L 2924/01079

(57) ABSTRACT

A semiconductor device has an electrical component and a plurality of e-bar structures disposed adjacent to the electrical component. An antenna interposer is disposed over a first surface of the e-bar structures. A redistribution layer is formed over a second surface of the e-bar structures opposite the first surface of the e-bar structures. The redistribution layer has a conductive layer and an insulating layer formed over the conductive layer. An encapsulant is deposited over the electrical component. The antenna interposer has a first conductive layer, an insulating layer formed over the first conductive layer, and a second conductive layer formed over the insulating layer. The second conductive layer can be arranged as a plurality of islands or in a serpentine pattern.

### FIELD OF THE INVENTION

The present invention relates in general to semiconductor devices and, more particularly, to a semiconductor device and method of integrating an eWLB with vertical e-bar structures and RF antenna interposer.

### BACKGROUND OF THE INVENTION

Semiconductor devices are commonly found in modern electrical products. Semiconductor devices perform a wide range of functions, such as signal processing, high-speed calculations, transmitting and receiving electromagnetic signals, controlling electrical devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices often contain a semiconductor die or substrate with electrical interconnect structures, e.g., redistribution layers (RDL) formed over one or more surfaces of the semiconductor die or substrate to perform necessary electrical functions. A vertical interconnect structure disposed adjacent to the semiconductor die is electrically connected to the RDL and an encapsulant covers the vertical interconnect structure and semiconductor die.

A semiconductor device may require an antenna for RF communications. It would be desirable to integrate the antenna function with the vertical and horizontal interconnect features of the semiconductor device.

### BRIEF DESCRIPTION OF THE DRAWINGS

FIGS. 1a-1c illustrate a semiconductor wafer with a plurality of semiconductor die separated by a saw street;

FIGS. 2a-21 illustrate a process of forming an e-bar substrate;

FIGS. 3a-3c illustrate another process of forming an e-bar substrate;

FIGS. 4a-4d illustrate a process of disposing an electrical component with adjacent e-bar structures as an eWLB;

FIGS. 5a-5e illustrate another process of disposing an electrical component with adjacent e-bar structures as an eWLB;

FIGS. 6a-6f illustrate a process of forming an encapsulant and RDL around the electrical component and e-bar structures;

FIGS. 7a-7f illustrate a process of forming an antenna interposer;

FIGS. 8a-8d illustrate integrating the eWLB with the antenna interposer;

FIG. 9 illustrates the AoP post singulation with an over-molded electrical component;

FIG. 10 illustrates the AoP with exposed electrical components;

FIG. 11 illustrates the AoP with partial underfill around the bumps of the antenna interposer;

FIG. 12 illustrates the AoP with underfill between the eWLB and antenna interposer; and

FIG. 13 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements having a similar function are assigned the same reference number in the figures. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

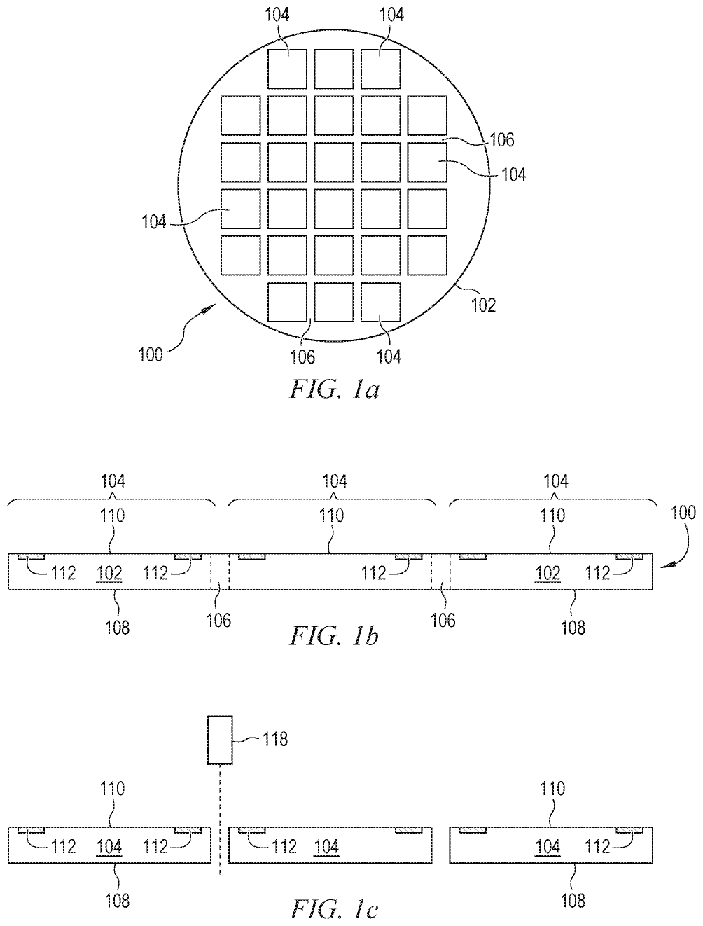

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or known good unit (KGD/KGU) post singulation.

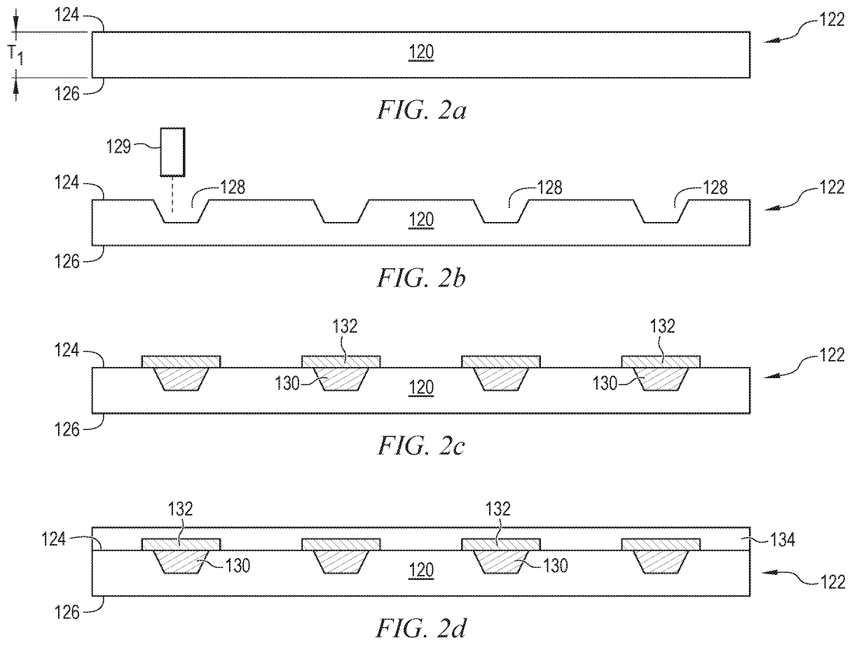

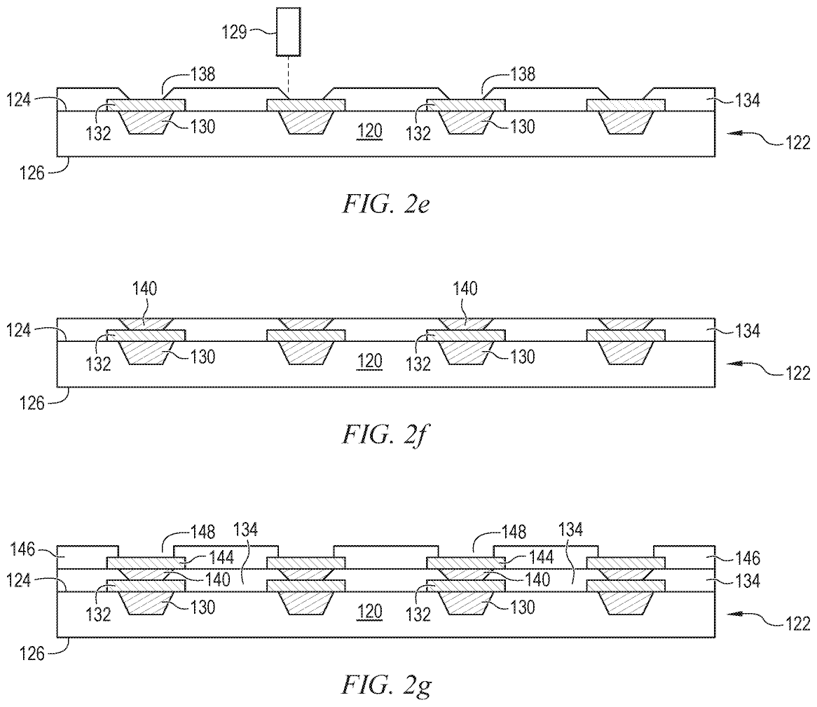

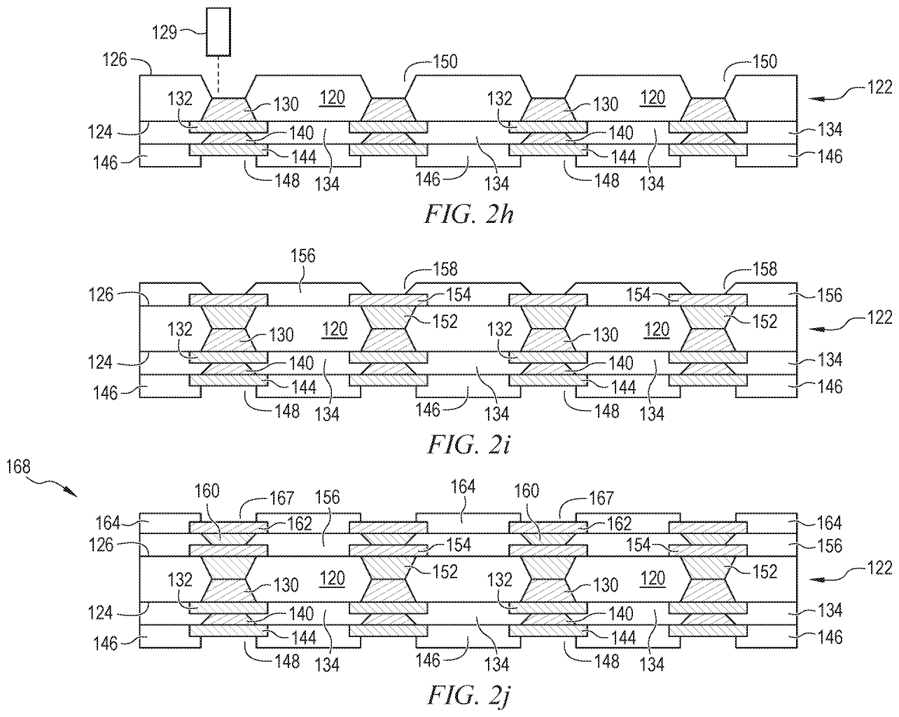

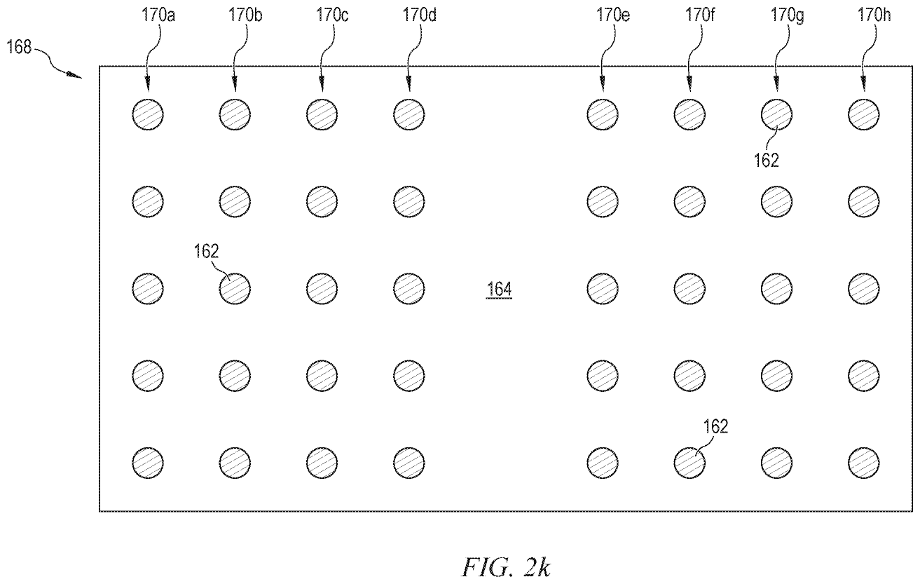

FIG. 2a illustrates a portion of base or core layer 120 for an embedded bar (e-bar) wafer or substrate 122 containing one or more layers of SiO2, Si3N4, SiON, Ta2O5, Al2O3, solder resist, polyimide, BCB, PBO, and other material having similar insulating and structural properties. Core layer 120 can also be a multi-layer flexible laminate, ceramic, copper clad laminate (CCL), glass, or epoxy molding compound. In another embodiment, base core layer 120 can also be any suitable laminate interposer, PCB, wafer-form, strip interposer, leadframe, or other type of substrate. Core layer 120 may include one or more laminated layers of polytetrafluoroethylene (PTFE) pre-impregnated (prepreg), FR-4, FR-1, CEM-1, or CEM-3 with a combination of phenolic cotton paper, epoxy, resin, woven glass, matte glass, polyester, and other reinforcement fibers or fabrics. Core layer 120 has a thickness T1 of 150.0 micrometers (μm) and includes first major surface 124 and second major surface 126 opposite surface 124.

In FIG. 2b, an opening or via 128 is formed in surface 124 of core layer 120 using an etching process or laser direct ablation (LDA) using laser 129, to a depth of about half of T1.

In FIG. 2c, conductive layer 130 is formed within openings 128 using PVD, CVD, electrolytic plating, electroless plating process, or other suitable metal deposition process. Conductive layer 130 can be one or more layers of Al, Cu, Sn, Ni, Au, Ag, or other suitable electrically conductive material. Portions of conductive layer 130 can be electrically common or electrically isolated depending on the design and function of electrical components attached thereto.

In FIG. 2d, conductive layer 132 is formed over conductive layer 130 and surface 124 of core layer 120 using PVD, CVD, electrolytic plating, electroless plating process, or other suitable metal deposition process. Conductive layer 132 can be one or more layers of Al, Cu, Sn, Ni, Au, Ag, or other suitable electrically conductive material. In one embodiment, conductive layer 132 has a thickness of 24.0±7.0 μm. Portions of conductive layer 132 can be electrically common or electrically isolated depending on the design and function of electrical components attached thereto.

An insulating or passivation layer 134 is formed over conductive layer 132 and surface 124 of core layer 120 using PVD, CVD, printing, lamination, spin coating, spray coating, sintering or thermal oxidation. Insulating layer 134 contains one or more layers of SiO2, Si3N4, SiON, Ta2O5, Al2O3, solder resist, polyimide, BCB, PBO, and other material having similar insulating and structural properties. In one embodiment, insulating layer 134 has a thickness of 64.0 μm. In FIG. 2e, portions of insulating layer 134 are removed using an etching process or LDA with a laser like 129 to form openings or vias 138 extending to conductive layer 132 for further electrical interconnect.

In FIG. 2f, conductive layer 140 is formed within openings 138 using PVD, CVD, electrolytic plating, electroless plating process, or other suitable metal deposition process. Conductive layer 140 can be one or more layers of Al, Cu, Sn, Ni, Au, Ag, or other suitable electrically conductive material. Portions of conductive layer 140 can be electrically common or electrically isolated depending on the design and function of electrical components attached thereto.

In FIG. 2g, conductive layer 144 is formed over conductive layer 140 and insulating layer 134 using PVD, CVD, electrolytic plating, electroless plating process, or other suitable metal deposition process. Conductive layer 144 can be one or more layers of Al, Cu, Sn, Ni, Au, Ag, or other suitable electrically conductive material. Conductive layer 144 operates as a contact pad for a later-formed RDL. In one embodiment, conductive layer 144 has a thickness of 24.0±7.0 μm. Conductive layer 144 operates as a contact pad for later-formed bumps. Portions of conductive layer 144 can be electrically common or electrically isolated depending on the design and function of electrical components attached thereto.

An insulating or passivation layer 146 is formed over conductive layer 144 and insulating layer 134 using PVD, CVD, printing, lamination, spin coating, spray coating, sintering or thermal oxidation. Insulating layer 146 contains one or more layers of SiO2, Si3N4, SiON, Ta2O5, Al2O3, solder resist, polyimide, BCB, PBO, and other material having similar insulating and structural properties. In one embodiment, insulating layer 146 has a thickness of 15.0±7.5 μm. Portions of insulating layer 146 are removed using an etching process or LDA with a laser like 129 to form openings or vias 148 extending to conductive layer 144 for further electrical interconnect.

The partial e-bar substrate from FIG. 2g is inverted and opening or via 150 is formed in surface 126 of core layer 120 using an etching process or LDA with a laser like 129 and extending to conductive layer 130, as shown in FIG. 2h.

In FIG. 2i, conductive layer 152 is formed within openings 150, similar to FIG. 2c. Conductive layer 154 is formed over conductive layer 152 and surface 126 of core layer 120, similar to FIG. 2d. In one embodiment, conductive layer 154 has a thickness of 24.0±7.0 μm. An insulating or passivation layer 156 is formed over conductive layer 152 and surface 126 of core layer 120. In one embodiment, insulating layer 156 has a thickness of 24.0±7.0 μm. Portions of insulating layer 156 are removed with a laser like 129 to form openings or vias 158 extending to conductive layer 152 for further electrical interconnect, similar to FIG. 2e.

In FIG. 2j, conductive layer 160 is formed within openings 158, similar to FIG. 2f. Conductive layer 162 is formed over conductive layer 160 and insulating layer 156, similar to FIG. 2g. In particular, conductive layer 162 is made with a thickness of about 24.0±7.0 μm. Conductive layer 162 operates as a contact pad for later-formed bumps. An insulating or passivation layer 164 is formed over conductive layer 160 and insulating layer 156. In one embodiment, insulating layer 164 has a thickness of 15.0±7.5 μm. Portions of insulating layer 164 are removed with a laser like 129 to form openings or vias 167 extending to conductive layer 162 for further electrical interconnect.

The combination of conductive layers 130, 132, 140, 144, 152, 154, 160, and 162, as well as core layer 120 and insulating layers 134, 146, 156, and 164, constitute e-bar wafer or substrate 168. The conductive layers 130, 132, 140, 144, 152, 154, 160, and 162 provide vertical electrical interconnect through e-bar substrate 168. FIG. 2k is a top view of e-bar substrate 168 with an array of the e-bar structures 170a-170h, visible as conductive layer 162 through insulating layer 164.

In FIG. 2l, e-bar substrate 168 is singulated using a laser cutting tool or saw blade 172, leaving individual e-bar structures 170a-170d. Post singulation, each e-bar structure 170a-170d is made of a portion of conductive layers 130, 132, 140, 144, 152, 154, 160, and 162, as well as core layer 120 and insulating layers 134, 146, 156, and 164, from e-bar substrate 168. In one embodiment, e-bar substrate 170a-170d has a height H1 of 420 μm+35 μm, depending on substrate 120 and package thickness. With core layer 120, e-bar substrate 170a-170d are rigid and generally non-compressible to support an overlaying structure, such as an RDL, as described below.

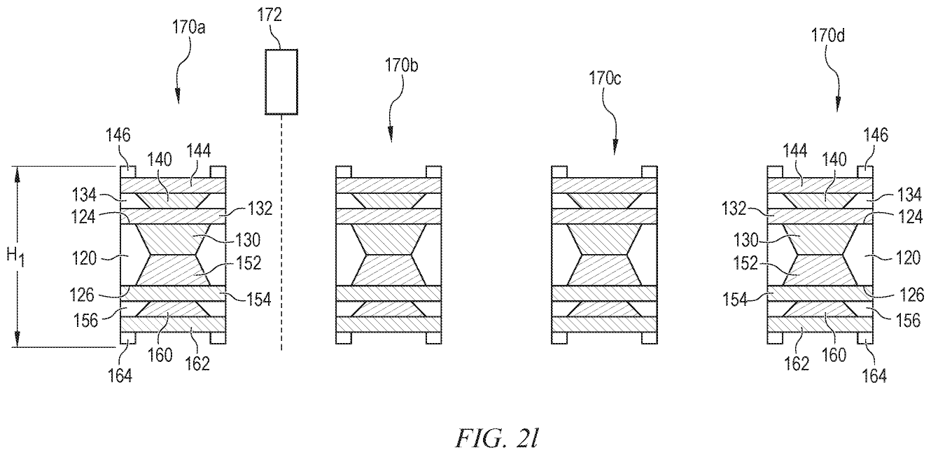

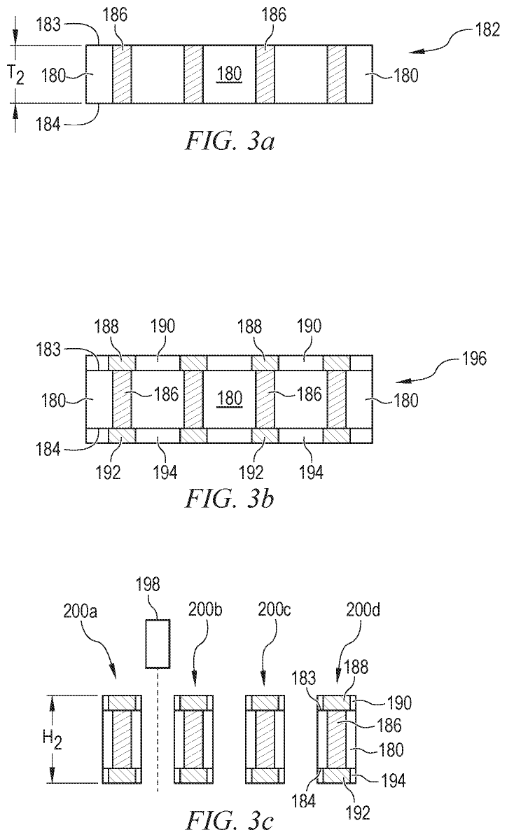

In another embodiment, FIG. 3a illustrates a portion of base or core layer 180 for an e-bar wafer or substrate 182 containing one or more layers of SiO2, Si3N4, SiON, Ta2O5, Al2O3, solder resist, polyimide, BCB, PBO, and other material having similar insulating and structural properties. Core layer 180 can also be a multi-layer flexible laminate, ceramic, CCL, glass, or epoxy molding compound. In another embodiment, base core layer 180 can also be any suitable laminate interposer, PCB, wafer-form, strip interposer, leadframe, or other type of substrate. Core layer 180 may include one or more laminated layers of PTFE prepreg, FR-4, FR-1, CEM-1, or CEM-3 with a combination of phenolic cotton paper, epoxy, resin, woven glass, matte glass, polyester, and other reinforcement fibers or fabrics. Core layer 180 has a thickness T2 of 150.0 μm and includes first major surface 183 and second major surface 184 opposite surface 183.

An opening or via is formed in surface 183 of core layer 180 using an etching process or LDA. The via can extend through core layer 180, or to a depth of about half of T2, similar to FIG. 2b. Conductive layer 186 is formed within the openings using PVD, CVD, electrolytic plating, electroless plating process, or other suitable metal deposition process. Conductive layer 186 can be one or more layers of Al, Cu, Sn, Ni, Au, Ag, or other suitable electrically conductive material. Portions of conductive layer 186 can be electrically common or electrically isolated depending on the design and function of electrical components attached thereto. If half of the via is filled with conductive layer 186 in accordance with FIGS. 2b-2c, then the other half of the via and conductive layer 186 would be formed similar to FIGS. 2h-21.

In FIG. 3b, conductive layer 188 is formed over conductive layer 186 and surface 183 of core layer 180 using PVD, CVD, electrolytic plating, electroless plating process, or other suitable metal deposition process. Conductive layer 188 can be one or more layers of Al, Cu, Sn, Ni, Au, Ag, or other suitable electrically conductive material. In one embodiment, conductive layer 188 has a thickness of 24.0±7.0 μm. Portions of conductive layer 188 can be electrically common or electrically isolated depending on the design and function of electrical components attached thereto.

An insulating or passivation layer 190 is formed over conductive layer 188 and surface 183 of core layer 180 using PVD, CVD, printing, lamination, spin coating, spray coating, sintering or thermal oxidation. Insulating layer 190 contains one or more layers of SiO2, Si3N4, SiON, Ta2O5, Al2O3, solder resist, polyimide, BCB, PBO, and other material having similar insulating and structural properties. In one embodiment, insulating layer 190 has a thickness of 64.0 μm.

Conductive layer 192 is formed over conductive layer 186 and surface 184 of core layer 180 using PVD, CVD, electrolytic plating, electroless plating process, or other suitable metal deposition process. Conductive layer 192 can be one or more layers of Al, Cu, Sn, Ni, Au, Ag, or other suitable electrically conductive material. In one embodiment, conductive layer 192 has a thickness of 24.0±7.0 μm. Portions of conductive layer 192 can be electrically common or electrically isolated depending on the design and function of electrical components attached thereto.

An insulating or passivation layer 194 is formed over conductive layer 192 and surface 184 of core layer 180 using PVD, CVD, printing, lamination, spin coating, spray coating, sintering or thermal oxidation. Insulating layer 194 contains one or more layers of SiO2, Si3N4, SiON, Ta2O5, Al2O3, solder resist, polyimide, BCB, PBO, and other material having similar insulating and structural properties. In one embodiment, insulating layer 194 has a thickness of 64.0 μm.

The combination of conductive layers 186, 188, and 192, as well as core layer 180 and insulating layers 190 and 194, constitute e-bar wafer or substrate 196. The conductive layers 186, 188, and 192 provide vertical electrical interconnect through e-bar substrate 196. A cross-sectional top view of conductive layer 186 or 188 would be similar to FIG. 2k, as an array of the e-bar structures.

In FIG. 3c, e-bar substrate 196 is singulated using a laser cutting tool or saw blade 198, leaving individual e-bar structures 200a-200d. Post singulation, each e-bar structure 200a-200d is made of a portion of conductive layers 186, 188, and 192, as well as core layer 180 and insulating layers 190 and 194, from e-bar substrate 196. In one embodiment, e-bar structures 200a-200d have a height H2 of 420 μm+35 μm, depending on substrate 180 and package thickness. With core layer 180, e-bar structures 200a-200d are rigid and generally non-compressible to support an overlaying structure, such as an RDL, as described below.

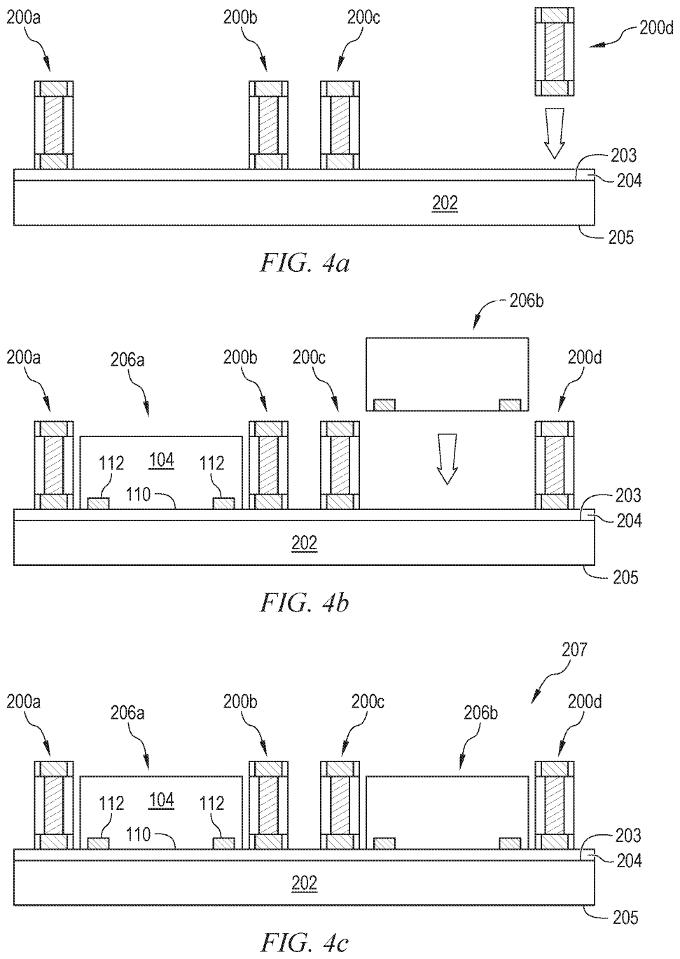

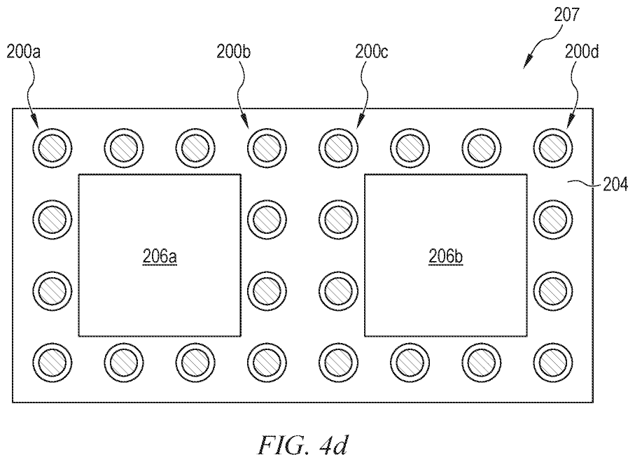

FIG. 4a shows a temporary substrate or carrier 202 containing sacrificial core material, such as silicon, polymer, beryllium oxide, glass, or other suitable low-cost, rigid material for structural support. Substrate 202 has major surface 203 and major surface 205, opposite surface 203. In one embodiment, carrier 202 is a support structure with a temporary bonding layer 204 formed over the carrier. Temporary bonding layer 204 can be a film or foil bonded to surface 203.

E-bar structures 200a-200d from FIG. 3c are positioned over carrier 202 using a pick and place operation. E-bar structures 200a-200d are brought into contact with bonding layer 204. Alternatively, e-bar structures 170a-170d can be disposed over and brought into contact with bonding layer 204.

In FIG. 4b, electrical components 206a-206b are disposed over surface 203 of substrate 202. Electrical component 206a-206b can be similar to, or made similar to, semiconductor die 104 from FIG. 1c with conductive layer 112 oriented toward surface 203 of substrate 202. Alternatively, electrical components 206a-206b can include other semiconductor die, semiconductor packages, surface mount devices, RF components, discrete electrical devices, or integrated passive devices (IPD).

Electrical components 206a-206b are positioned over substrate 202 using a pick and place operation. Electrical components 206a-206b are brought into contact with bonding layer 204, between e-bar structures 200a-200b and 200c-200d, respectively. FIG. 4c illustrates electrical components 206a-206b and e-bar structures 200a-200d bonded to substrate 202, as assembly 207. Electrical components 206a-206b can be mounted to substrate 202 prior to e-bar structures 200a-200d. FIG. 4d is a top view of assembly 207 with individual e-bar structures like 200a-200d formed around or adjacent to a side of electrical components 206a-206b over bonding layer 204 and substrate 202.

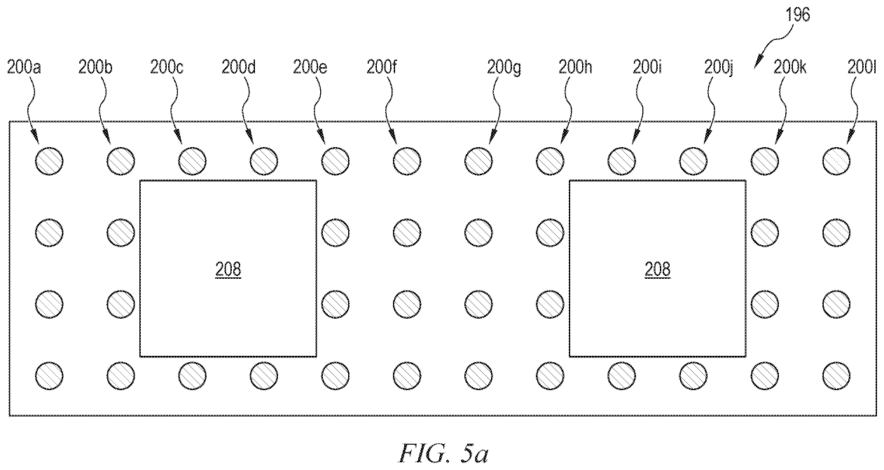

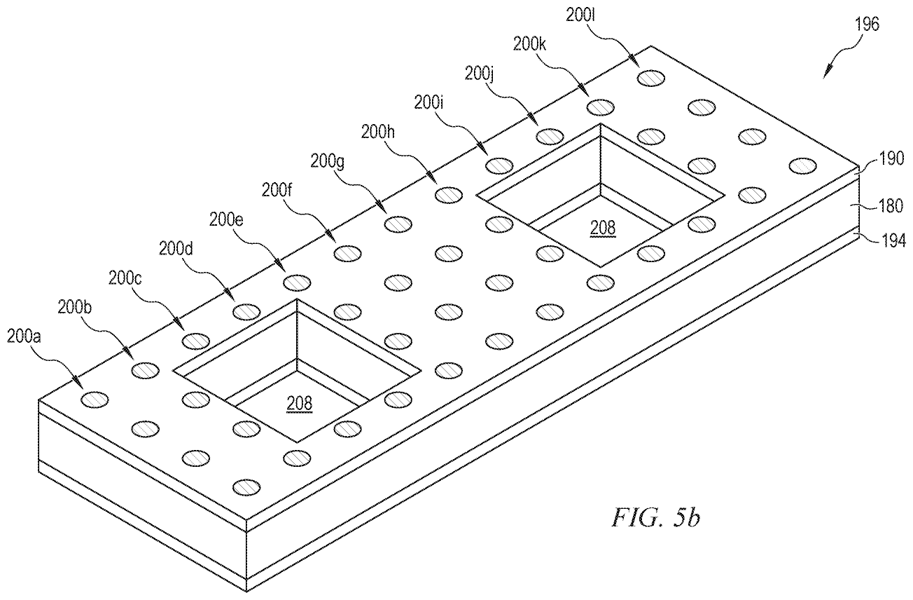

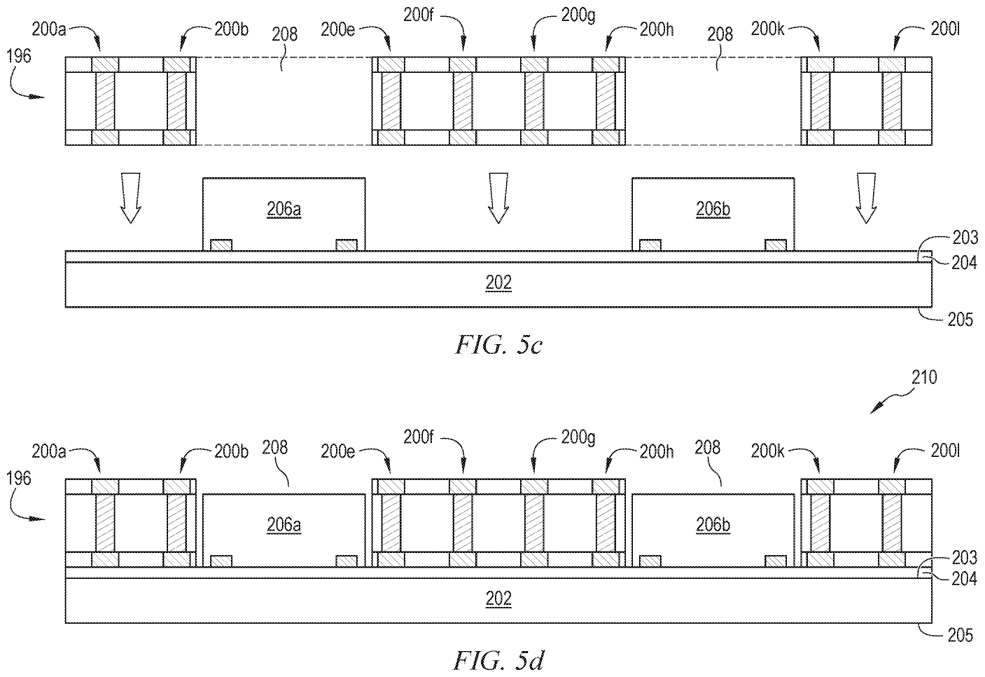

In another embodiment, e-bar substrate 196 from FIG. 3b is disposed over and brought into contact with bonding layer 204. In this case, the e-bar structures are not singulated into individual units, but rather remain an integral part of e-bar substrate 196, as shown in FIG. 5a. E-bar substrate 196 can have addition e-bar structures like 200a-2001, made similar to e-bar structures 200a-200d. Openings 208 are formed in to accommodate electrical components 206a-206b. FIG. 5b is a perspective view of e-bar substrate 196 with e-bar structures 200a-2001 and openings 208.

In FIG. 5c, electrical components 206a-206b are brought into contact with bonding layer 204, similar to FIG. 4b. E-bar substrate 196 from FIG. 5b is disposed over and brought into contact with bonding layer 204 with electrical components 206a-206b occupying openings 208. FIG. 5d illustrates electrical components 206a-206b and e-bar substrate 196 with integrated e-bar structures 200a-2001 bonded to substrate 202, as assembly 210. FIG. 5e is a top view of assembly 210 with e-bar substrate 196 containing integrated e-bar structures 200a-2001 disposed around or adjacent to a side of electrical components 206a-206b over substrate 202.

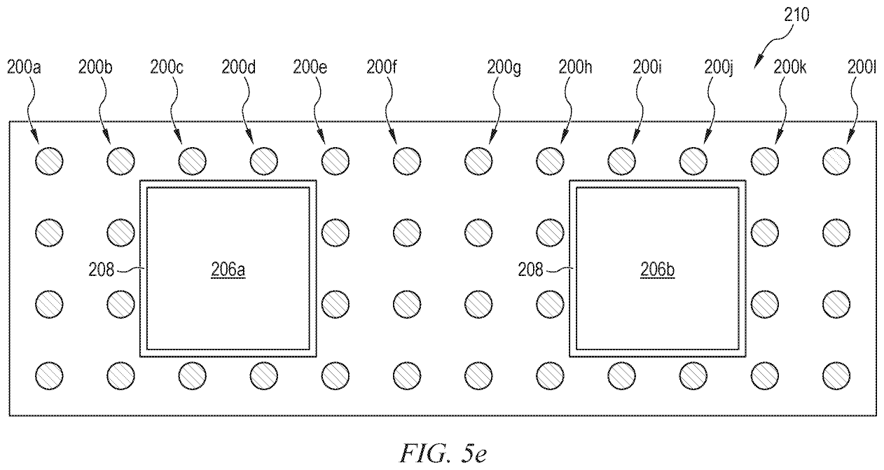

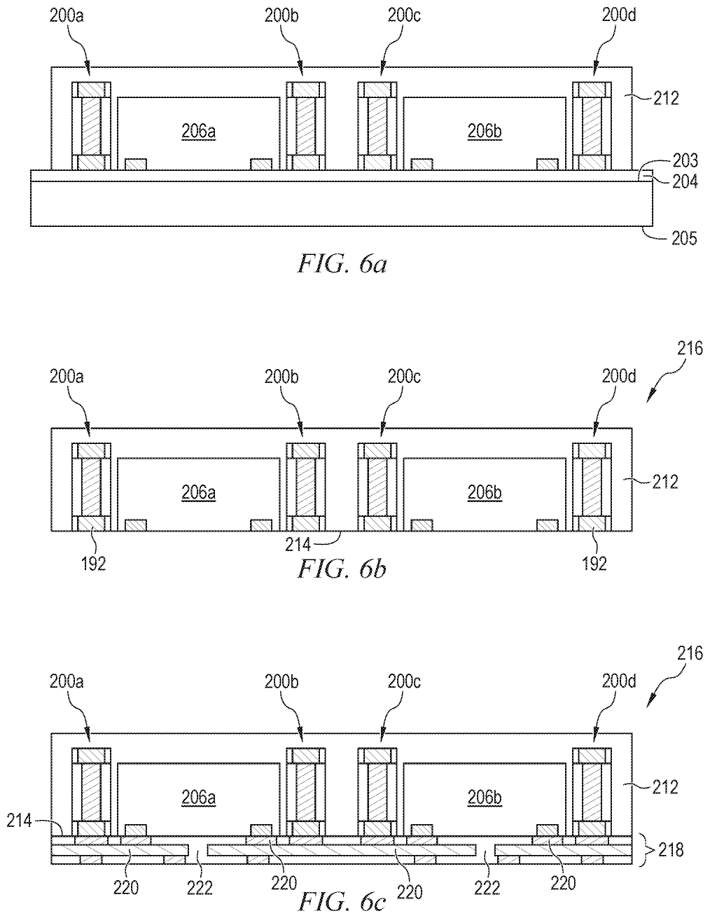

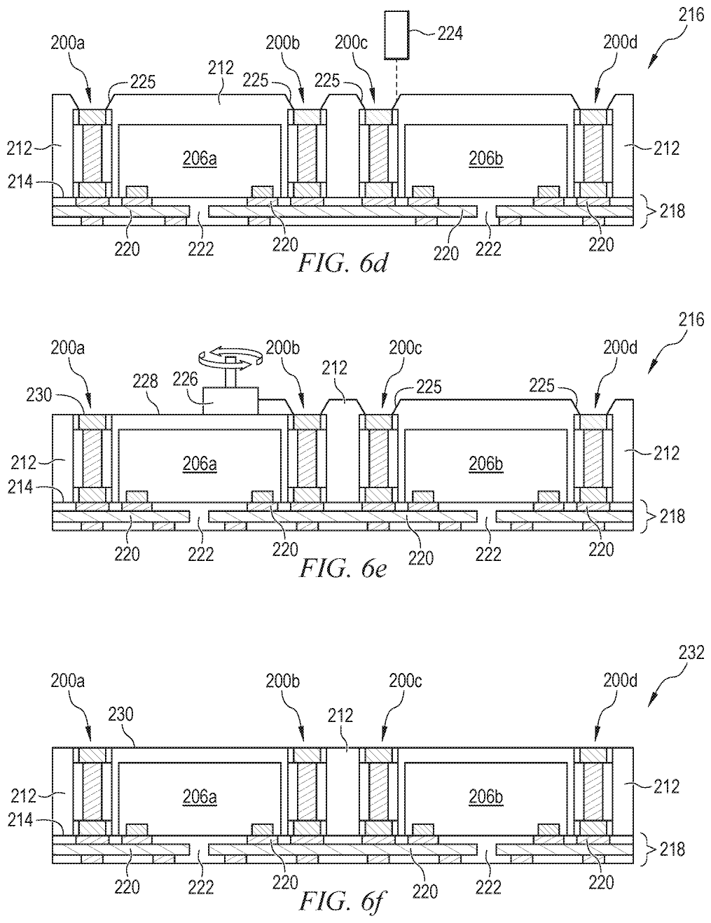

Continuing from assembly 207 in FIGS. 4c-4d or from assembly 210 in FIGS. 5d-5e, encapsulant or molding compound 212 is deposited over and around electrical components 206a-206b and e-bar structures like 200a-200d (or e-bar substrate 196) using a paste printing, compressive molding, transfer molding, liquid encapsulant molding, vacuum lamination, spin coating, or other suitable applicator, as shown in FIG. 6a. To simplify the description, assembly 207 is used for the remaining figures. A similar process would apply to assembly 210. Encapsulant 212 can be liquid or granular polymer composite material, such as epoxy resin with filler, epoxy acrylate with filler, or polymer with proper filler. Encapsulant 212 is non-conductive, provides structural support, and environmentally protects the semiconductor device from external elements and contaminants.

In FIG. 6b, carrier 202 and bonding layer 204 are removed by chemical etching, chemical mechanical polishing (CMP), mechanical peel-off, mechanical grinding, thermal bake, ultra-violet (UV) light, or wet stripping to expose conductive layer 112 of electrical components 206a-206b, conductive layer 192 of e-bar structures 200a-200d, and surface 214 of encapsulant 212. Reconstituted embedded wafer level ball grid array package (eWLB) 216, comprising electrical components 206a-206b, e-bar structures 200a-200d, and encapsulant 212, is ready for a multi-layer RDL buildup interconnect structure over surface 110 of electrical components 206a-206b, surface 214 of encapsulant 212, and conductive layer 112 to provide electrical interconnect for the semiconductor die, as well as external electrical components. Reconstituted eWLB 216 operates as a substrate, with e-bar structures, to form the multi-layer RDL buildup interconnect structure.

FIG. 6c shows a multi-redistribution layer (RDL) interconnect structure 218 including conductive layers 220 and insulting layers 222. Conductive layer 220 are formed using PVD, CVD, electrolytic plating, electroless plating process, or other suitable metal deposition process. Conductive layers 220 can be one or more layers of Al, Cu, Sn, Ni, Au, Ag, or other suitable electrically conductive material. Conductive layer 220 is an RDL as it redistributes the electrical signal across and over electrical components 206a-206b and encapsulant 212. Portions of conductive layer 220 can be electrically common or electrically isolated depending on the design and function of semiconductor die 104 and other electrical components attached thereto. Insulating layers 222 are formed over and around conductive layers 220 using PVD, CVD, printing, lamination, spin coating, spray coating, sintering or thermal oxidation. Insulating layers 222 contains one or more layers of SiO2, Si3N4, SiON, Ta2O5, Al2O3, solder resist, polyimide, BCB, PBO, and other material having similar insulating and structural properties. In FIG. 6d, portions of encapsulant 212 are removed using an etching process or LDA with laser 224 to form openings or vias 225 extending to conductive layers 188 of e-bar structures 200a-200d for further electrical interconnect.

In FIG. 6e, encapsulant 212 undergoes a grinding operation with grinder 226 to planarize surface 228 of encapsulant 212, surface 230 of conductive layer 188, and insulating layer 190. FIG. 6f shows the planarized surface 228 of encapsulant 212 and surface 230 of conductive layer 188, as eWLB 232 with e-bar structures 200a-200d.

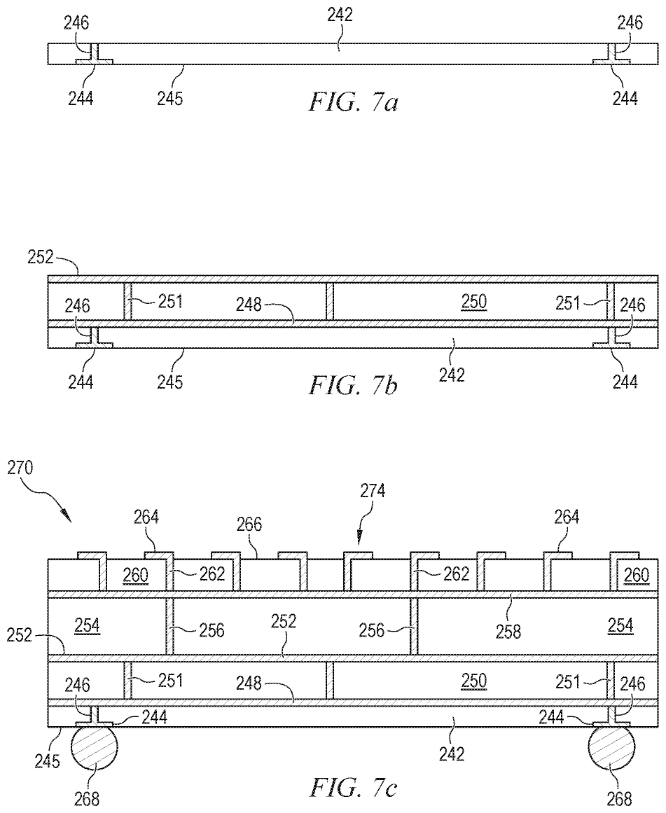

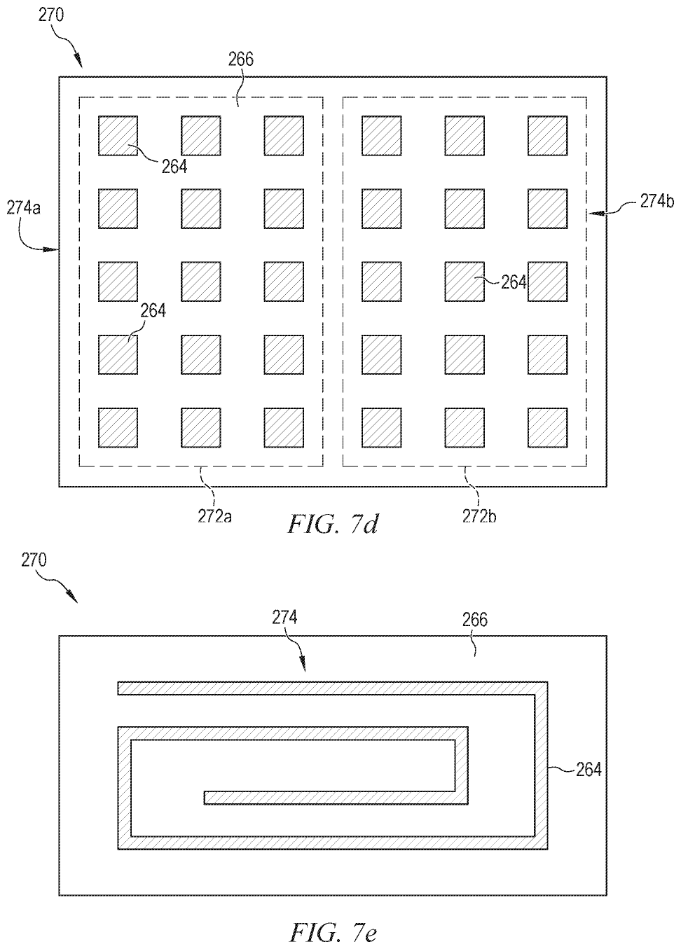

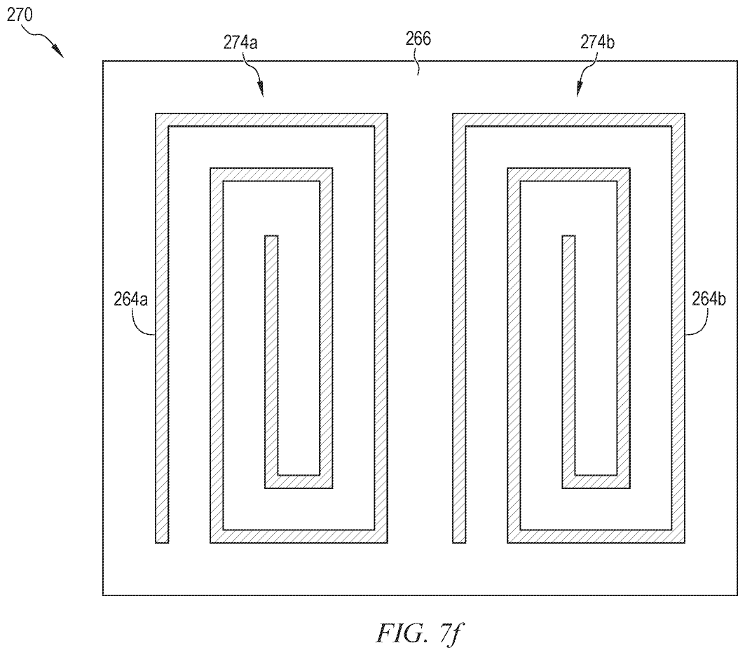

FIGS. 7a-7f illustrate a process of forming an RF antenna interposer or substrate. In FIG. 7a, insulating layer 242 is made with SiO2, Si3N4, SiON, Ta2O5, Al2O3, solder resist, polyimide, polymer, BCB, PBO, and other material having similar insulating and structural properties. Conductive layer 244 is formed over surface 245 of insulating layer 242. Conductive layer 244 can be one or more layers of Al, Cu, Sn, Ni, Au, Ag, or other suitable electrically conductive material. Conductive layer 244 provides horizontal electrical interconnect across insulating layer 242, including surface 245. A plurality of vias is formed through insulating layer 242 by etching, drilling, or LDA. The vias are filled with conductive material to form conductive vias 246 for vertical electrical interconnect through insulating layer 242 to conductive layer 244.

In FIG. 7b, conductive layer 248 is formed over insulating layer 242. Conductive layer 248 can be one or more layers of Al, Cu, Sn, Ni, Au, Ag, or other suitable electrically conductive material. Conductive layer 248 provides horizontal electrical interconnect across insulating layer 242 and electrically connects to conductive vias 246. An insulating layer 250 is formed over conductive layer 248. Insulating layer 250 is made with SiO2, Si3N4, SiON, Ta2O5, Al2O3, solder resist, polyimide, polymer, BCB, PBO, and other material having similar insulating and structural properties. A plurality of vias is formed through insulating layer 250 by etching, drilling, or LDA. The vias are filled with conductive material to form conductive vias 251 for vertical electrical interconnect through insulating layer 250 to conductive layer 248. Conductive layer 252 is formed over insulating layer 250. Conductive layer 252 can be one or more layers of Al, Cu, Sn, Ni, Au, Ag, or other suitable electrically conductive material. In one embodiment, conductive layer 252 provides a ground plane across insulating layer 250 and electrically connects to conductive vias 251.

In FIG. 7c, insulating layer 254 is formed over conductive layer 252. Insulating layer 254 is made with SiO2, Si3N4, SiON, Ta2O5, Al2O3, solder resist, polyimide, polymer, BCB, PBO, and other material having similar insulating and structural properties. A plurality of vias is formed through insulating layer 254 by etching, drilling, or LDA. The vias are filled with conductive material to form conductive vias 256 for vertical electrical interconnect through insulating layer 254 to conductive layer 252. Conductive layer 258 is formed over insulating layer 254. Conductive layer 258 can be one or more layers of Al, Cu, Sn, Ni, Au, Ag, or other suitable electrically conductive material. Conductive layer 258 provides horizontal electrical interconnect across insulating layer 254 and electrically connects to conductive vias 256. Conductive layer 258 can be configured as an RF antenna, similar to RF antenna 194, embedded within RF antenna interposer 270. An insulating layer 260 is formed over conductive layer 258. Insulating layer 260 is made with SiO2, Si3N4, SiON, Ta2O5, Al2O3, solder resist, polyimide, polymer, BCB, PBO, and other material having similar insulating and structural properties. A plurality of vias is formed through insulating layer 260 by etching, drilling, or LDA. The vias are filled with conductive material to form conductive vias 262 for vertical electrical interconnect through insulating layer 260 to conductive layer 258. Conductive layer 264 is formed over surface 266 of insulating layer 260 and electrically connects to conductive vias 262. Conductive layer 264 can be one or more layers of Al, Cu, Sn, Ni, Au, Ag, or other suitable electrically conductive material. Conductive layer 264 operates as RF antenna 274 exposed from surface 266 of RF antenna interposer 270.

An electrically conductive bump material is deposited over conductive layer 244 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 244 using a suitable attachment or bonding process. In one embodiment, the bump material is reflowed by heating the material above its melting point to form balls or bumps 268. In one embodiment, bump 268 is formed over an under bump metallization (UBM) having a wetting layer, barrier layer, and adhesive layer. Bump 268 can also be compression bonded or thermocompression bonded to conductive layer 244. Bump 268 represents one type of interconnect structure that can be formed over conductive layer 244. The interconnect structure can also use bond wires, conductive paste, stud bump, micro bump, or other electrical interconnect.

FIG. 7d is a top view of RF antenna interposer 270. Conductive layer 264 includes an array of islands of conductive material in the form of conductive layer 264 suitable to provide transmission and reception of RF signals, i.e., an RF antenna. In particular, the array of islands of conductive layer 264 are exposed from surface 266 and extend substantially across the surface of RF antenna interposer 270 to improve RF transmission and reception performance and quality. In one embodiment, the entire array of islands of conductive material can be used as a single antenna 274 for RF transmission and reception of electrical components 206-206b in eWLB 232. Alternatively, a first group of islands of conductive material 272a serves as a first antenna 274a to provide RF transmission and reception for a first electrical component 206a. A second group of islands of conductive material 272b serves as a second antenna 194b to provide RF transmission and reception for a second electrical component 206b.

FIG. 7e is a top view of an alternate embodiment of RF antenna interposer 270. Conductive layer 264 includes a spiral shape of conductive material in the form of conductive layer 264 suitable to provide transmission and reception of RF signals. In particular, the spiral shape of conductive layer 264 is exposed from surface 266 and extends substantially across the surface of RF antenna interposer 270 to improve RF transmission and reception performance and quality. Conductive layer 264 serves as spiral-shaped RF antenna 274 to provide RF transmission and reception for electrical components 206a-206b. Conductive layer 264 can have other shapes, such as circular, oval, or other geometric pattern.

FIG. 7f is a top view of another embodiment of RF antenna interposer 270. Conductive layer 264 includes a plurality of spiral shapes of conductive material suitable to provide transmission and reception of RF signals. In particular, the spiral shapes of conductive layer 264 are exposed from surface 266 and extend substantially across the surface of RF antenna interposer 270 to improve RF transmission and reception performance and quality. In one embodiment, conductive layer 264a serves as a first spiral-shaped RF antenna 274a to provide RF transmission and reception for a first electrical component 206a. Conductive layer 264b serves as a second spiral-shaped RF antenna 274b to provide RF transmission and reception for a second electrical component 206b.

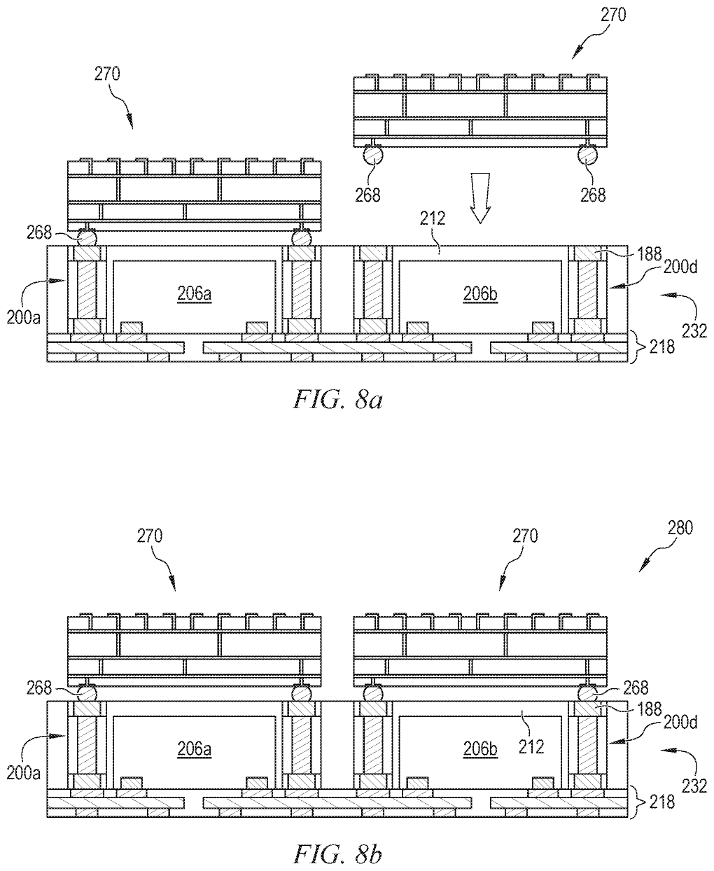

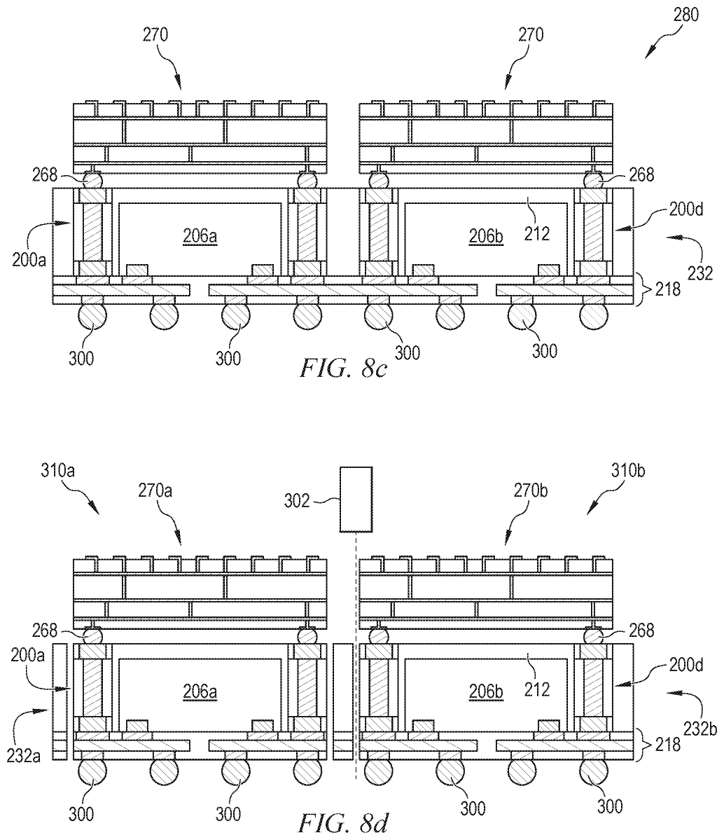

In FIG. 8a, RF antenna interposer 270 from FIGS. 7a-7f, is positioned over eWLB 232, from FIG. 6f, with bumps 268 aligned with conductive layer 188. RF antenna interposer 270 has substantially the same or similar footprint and occupies substantially the same or similar area as eWLB 232. RF antenna interposer 270 is lowered so that bumps 268 contact conductive layer 188 and the bumps are reflowed to electrically and mechanically join and integrate the RF antenna interposer to eWLB 232, shown as assembly 280 in FIG. 8b.

In FIG. 8c, an electrically conductive bump material is deposited over conductive layer 220 of RDL 218 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 220 using a suitable attachment or bonding process. In one embodiment, the bump material is reflowed by heating the material above its melting point to form balls or bumps 300. In one embodiment, bump 300 is formed over a UBM having a wetting layer, barrier layer, and adhesive layer. Bump 300 can also be compression bonded or thermocompression bonded to conductive layer 220. Bump 300 represents one type of interconnect structure that can be formed over conductive layer 220. The interconnect structure can also use bond wires, conductive paste, stud bump, micro bump, or other electrical interconnect.

In FIG. 8d, eWLB 232 with integrated RF antenna interposer 270, shown as assembly 280, is singulated using a laser cutting tool or saw blade 302, leaving individual eWLB antenna on packages (AoP) 310a, as a combination of eWLB 232a and RF antenna interposer 270a, and eWLB AoP 310b, as a combination of eWLB 232b and RF antenna interposer 270b, i.e. each as an eWLB package-on-package (Pop).

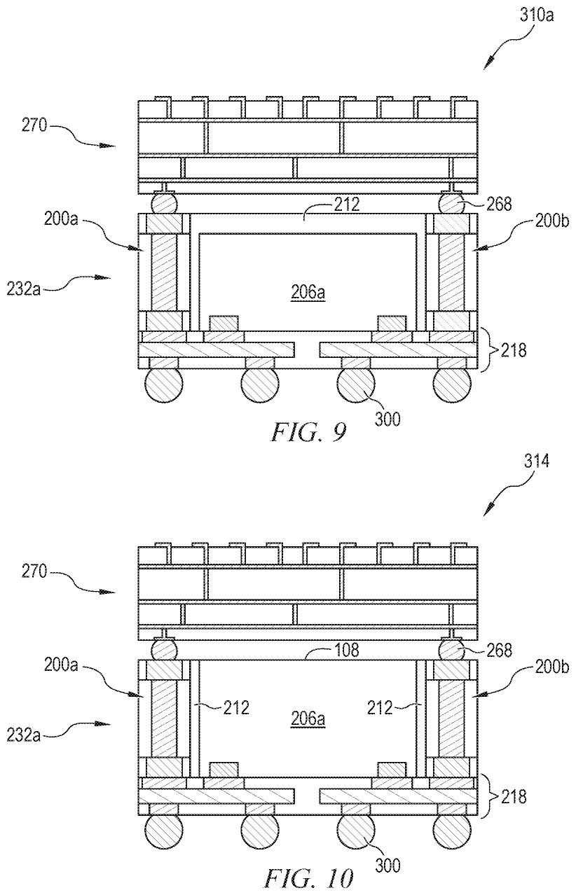

FIG. 9 illustrates eWLB AoP 310a post singulation. RF antenna interposer 270a provides the antenna function for RF electrical components 206a through e-bar structures 200a-200b. Similarly, RF antenna interposer 270b provides the antenna function for RF electrical components 206b through e-bar structures 200c-200d. A portion of encapsulant 212 remains over surface 108 of electrical component 206a. The eWLB AoP 310a and 310b are each an over-molded eWLB-POP structure with e-bar vertical interconnection and top antenna patterning substrate. RDL 218 provides electrical connection through bumps 300.

AoP 310a uses eWLB process such as LDA, grinding to expose e-bar structures 200a-200d, and antenna interposer stacking to achieve the eWLB-POP structure. E-bar structures 200a-200d provide vertical electrical interconnection between RF antenna 270a and electrical component 206a. Robust signal routing and design to have better high speed and high frequency performance.

FIG. 10 illustrates an embodiment of eWLB AoP 314 with encapsulant 212 coplanar with a top surface of e-bars 200a-200b, as well as surface 108 of electrical component 206a. The top surface of electrical component 206a is exposed from the eWLB-PoP structure while retaining the e-bar vertical interconnection and top antenna patterning substrate.

FIG. 11 illustrates an embodiment of eWLB AoP 320 with partial underfill material 322 deposited around bumps 268. Underfill material 322 can be an epoxy resin. The partial underfill protects bumps 268 and enhances thermal dissipation.

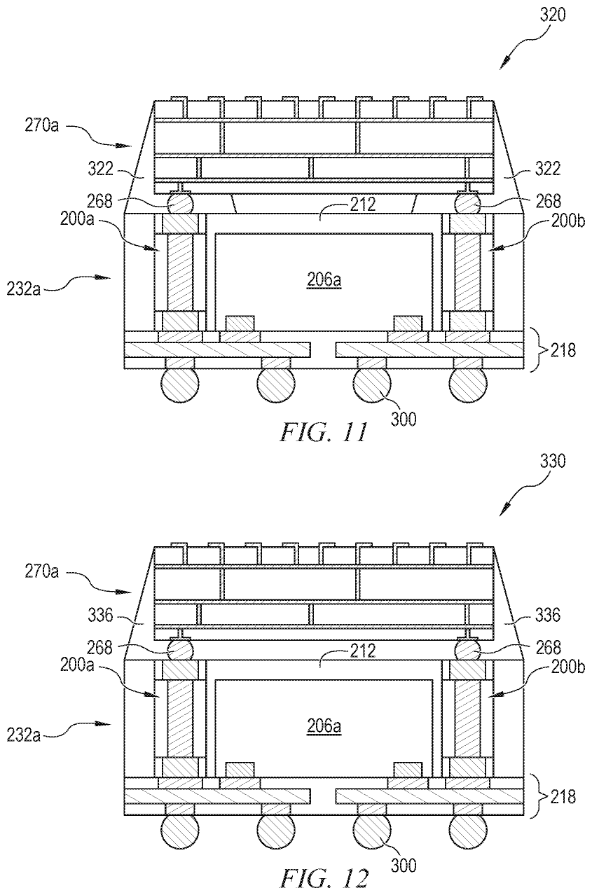

FIG. 12 illustrates an embodiment of eWLB AoP 330 with underfill material 336 deposited completely covering the package between RF antenna interposer 270a and eWLB 232a. Underfill material 336 can be an epoxy resin. The complete underfill material 336 protects bumps, as well as electrical component 206a, and enhances thermal dissipation.

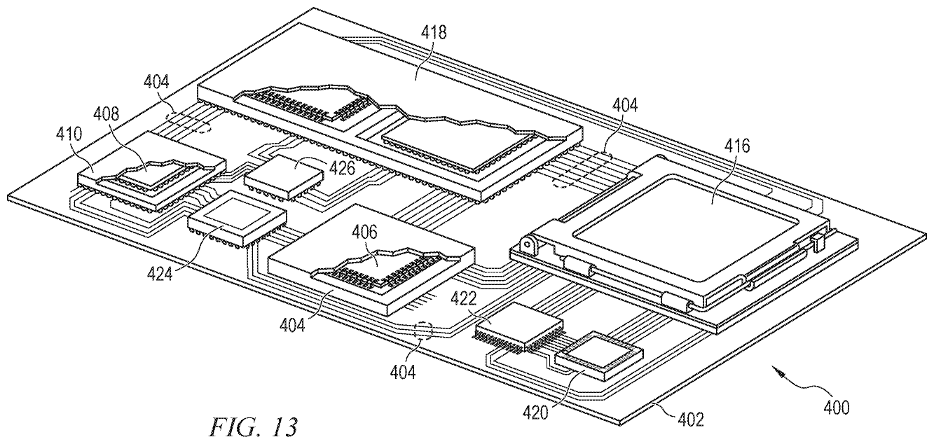

FIG. 13 illustrates electrical device 400 having a chip carrier substrate or PCB 402 with a plurality of semiconductor packages disposed on a surface of PCB 402, including eWLB AoP 310, 314, 320, and 330. Electrical device 400 can have one type of semiconductor package, or multiple types of semiconductor packages, depending on the application. Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 13, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a substrate including a plurality of e-bar structures disposed adjacent to an electrical component; and
an antenna interposer disposed over a first surface of the substrate.

2. The semiconductor device of claim 1, further including a redistribution layer formed over a second surface of the substrate opposite the first surface of the substrate.

3. The semiconductor device of claim 2, wherein the redistribution layer includes:
a conductive layer; and
an insulating layer formed over the conductive layer.

4. The semiconductor device of claim 1, further including an encapsulant deposited over the electrical component.

5. The semiconductor device of claim 1, wherein the antenna interposer includes:
a first conductive layer;
an insulating layer formed over the first conductive layer; and
a second conductive layer formed over the insulating layer.

6. The semiconductor device of claim 5, wherein the second conductive layer operates as an antenna.

7. A semiconductor device, comprising:
an electrical component;
a plurality of e-bar structures disposed adjacent to the electrical component; and
an antenna interposer disposed over a first surface of the e-bar structures.

8. The semiconductor device of claim 7, further including a redistribution layer formed over a second surface of the e-bar structures opposite the first surface of the e-bar structures.

9. The semiconductor device of claim 8, wherein the redistribution layer includes:
a conductive layer; and
an insulating layer formed over the conductive layer.

10. The semiconductor device of claim 7, further including an encapsulant deposited over the electrical component.

11. The semiconductor device of claim 7, wherein the antenna interposer includes:
a first conductive layer;
an insulating layer formed over the first conductive layer; and
a second conductive layer formed over the insulating layer.

12. The semiconductor device of claim 11, wherein the second conductive layer is arranged as a plurality of islands.

13. The semiconductor device of claim 11, wherein the second conductive layer is arranged in a serpentine pattern.

14. A method of making a semiconductor device, comprising:
providing a substrate including a plurality of e-bar structures disposed adjacent to an electrical component; and
disposing an antenna interposer over a first surface of the substrate.

15. The method of claim 14, further including forming a redistribution layer over a second surface of the substrate opposite the first surface of the substrate.

16. The method of claim 15, wherein forming the redistribution layer includes:
forming a conductive layer; and
forming an insulating layer over the conductive layer.

17. The method of claim 14, further including depositing an encapsulant over the electrical component.

18. The method of claim 14, wherein disposing the antenna interposer includes:
forming a first conductive layer;
forming an insulating layer over the first conductive layer; and
forming a second conductive layer over the insulating layer.

19. The method of claim 18, wherein the second conductive layer operates as an antenna.

20. A method of making a semiconductor device, comprising:
providing an electrical component;
disposing a plurality of e-bar structures adjacent to the electrical component; and
disposing an antenna interposer over a first surface of the e-bar structures.

21. The method of claim 20, further including forming a redistribution layer over a second surface of the e-bar structures opposite the first surface of the e-bar structures.

22. The method of claim 21, wherein forming the redistribution layer includes:
forming a conductive layer; and
forming an insulating layer over the conductive layer.

23. The method of claim 20, further including depositing an encapsulant over the electrical component.

24. The method of claim 20, wherein disposing the antenna interposer includes:
forming a first conductive layer;
forming an insulating layer over the first conductive layer; and
forming a second conductive layer over the insulating layer.

25. The method of claim 24, wherein the second conductive layer is arranged as a plurality of islands or in a serpentine pattern.
